(19) United States
(12) Patent Application Publication
(10) Pub. No.: US 2009/0321146 A1
(43) Pub. Date: Dec. 31, 2009

(54) Earth Boring Bit with DLC Coated Bearing and Seal

(75) Inventors: Aaron J. Dick, Houston, TX (US); Chih C. Lin, Spring, TX (US); Anton F. Zahradnik, Sugar Land, TX (US); Gregory L. Ricks, Spring, TX (US); Terry J. Koltermann, The Woodlands, TX (US)

Correspondence Address: BRACEWELL & GIULIANI LLP, P.O. BOX 61389, HOUSTON, TX, 77208-1389, US

(73) Assignee: Baker Hughes Incorporated, Houston, TX (US)

(21) Appl. No.: 12/556,325

(22) Filed: Sep. 9, 2009

Related U.S. Application Data
(63) Continuation-in-part of application No. 12/417,416, filed on Apr. 2, 2009.
Application No. 12/417,416 is a continuation-in-part of application No. 12/172,364, filed on Jul. 14, 2008.
(60) Provisional application No. 60/949,756, filed on Jul. 13, 2007.
(60) Provisional application No. 61/041,621, filed on Apr. 2, 2008.

(51) Int. Cl. E21B 10/25; E21B 10/08; E21B 10/22; C23C 16/50

(52) U.S. Cl. 175/371; 427/569

(57) ABSTRACT

A roller cone bit is provided that includes a wear resistant diamond-like carbon coating applied to a bearing shaft, where it is in sliding contact with the bearing seal. The wear resistant diamond-like carbon coating reduces wear and corrosion of the head bearing shaft sealing surface and provides extended life to the bearing seal.

### RELATED APPLICATIONS

This application is a continuation-in-part of co-pending application Ser. No. 12/417,416, filed on Apr. 2, 2009, which is a continuation-in-part application of U.S. patent application Ser. No. 12/172,364, filed Jul. 14, 2008, which claims priority to and the benefit of U.S. Provisional Application Ser. No. 60/949,756, filed Jul. 13, 2007, and also claims priority to and the benefit of co-pending U.S. Provisional Application Ser. No. 61/041,621, filed Apr. 2, 2008, the full disclosures of which are hereby incorporated by reference herein.

### BACKGROUND OF THE INVENTION

1. Field of the Invention

The present invention relates generally to drill bits for drilling into a subterranean formation, and more specifically to drill bits for drilling into a subterranean formation that include a wear resistant diamond-like carbon (DLC) coating applied to one or more of the inner surfaces of the drill bit and methods for applying a wear resistant DLC coating to one or more interior surfaces of the drill bit, to reduce wear on the seal and the surface of the drill bit.

2. Description of Related Art

Rotary-type drill bits include both rotary drag bits and roller-cone bits. Typically, in a rotary drag bit, fixed cutting elements are attached to the face of the drill bit. In a roller-cone arrangement, the drill bit typically has three cones, each independently rotatable with respect to the bit body supporting the cones through bearing assemblies. The cones carry either integrally formed teeth or separately formed inserts that provide the cutting action of the bit into the earthen formation.

The roller cones are typically attached to a bearing shaft that extends in a generally inward and downward orientation relative to the leg of the drill bit. Rotation of the roller cone is generally about an axis defined by the bearing shaft. The roller cone typically contacts the bearing shaft at a plurality of interior surfaces of the roller cone. The force applied to the drill bit during drilling operations is transmitted through the drill bit and to the interior surfaces of the roller cone and the bearing shaft.

While the application of hardened and wear resistant coatings to the outer wear surfaces of drill bits, such as the cutting elements, is known in the art, application of wear resistant coatings to the interior wear surfaces of drill bits is only recently gaining attention. Prior art methods have thus far been directed to the application of wear resistant coatings in an effort to reduce wear between interior contacting metal-metal surfaces, which can lead to the deterioration of the interior of the roller cone and/or the bearing shaft it contacts, thus leading to the need to replace the drill bit.

A seal is typically positioned between the bearing pin and the outside environment and is designed to keep lubrication in and around the bearing space and keeps contaminants, including drilling fluids and cuttings, out of the bearing space. The seal should apply enough pressure or squeeze around the bearing pin to prevent loss of lubrication, while at the same time preventing the influx of drilling fluids, however, at the same time, the pressure should be minimized to reduce friction and wear of the seal. Over time, friction between the rotating seal and the seal gland can result in wear of both the seal gland and the seal, thereby causing a decrease in the seal squeeze and failure of the drill bit.

While the prior art has focused on the need to reduce wear between metal-metal surfaces on drill bits, it is also known that during extended use, elastomeric seals wear due to friction as a result of contact with the bearing shaft. Prior art methods to reduce wear of the seal and improve the lifetime thereof have generally focused on the materials used for the seal and seal composition additives for increasing wear resistance. Prior art additives utilized for increased life in seals include molybdenum disulfide, graphite, nitrides and other known compounds, however these have only met with limited success. Thus, there exists a need for reducing seal wear and improving overall seal lifetimes through manipulation of the physical properties of the bearing shaft metal.

### SUMMARY OF THE INVENTION

The present invention provides a rotary-type drill bit for drilling subterranean formations and method for making the same. The bit according to the present invention includes a surface treatment for the interior portions of the drill bit to decrease seal and seal gland wear.

In one embodiment, a drill bit for drilling a subterranean formation is provided. The drill bit includes at least one leg and a cantilevered bearing shaft comprising a base formed on the at least one leg and having a substantially cylindrical surface extending from the base defining a longitudinal axis. A roller cone is disposed about the bearing shaft and is configured to rotate about the longitudinal axis. The roller cone includes an exterior surface for contacting the subterranean formation and an interior surface disposed about the bearing shaft. A sealing element is disposed circumferentially about the bearing shaft and is positioned between the interior surface of the roller cone and an exterior surface of the bearing shaft. At least a portion of the exterior surface of the bearing shaft that contacts the sealing element includes a diamond-like carbon coating.

In another embodiment of the present invention, a drill bit for drilling a subterranean formation is provided that includes at least one leg and a cantilevered bearing shaft that includes a base formed on the at least one leg and includes a substantially cylindrical surface extending from the base defining a longitudinal axis. A roller cone is disposed about the bearing shaft and is configured to rotate about the longitudinal axis. The roller cone includes an exterior surface for contacting the subterranean formation and an interior surface disposed about the bearing shaft. A sealing element is disposed circumferentially about the bearing shaft and is positioned between the interior surface of the roller cone and an exterior surface of the bearing shaft. The drill bit further includes a bearing sleeve secured to base of the bearing shaft, thereby forming a portion of the exterior surface of the bearing shaft that contacts the sealing element, wherein at least a portion of the exterior surface of the bearing sleeve that contacts the sealing element includes a diamond-like carbon coating.

In another embodiment, a drill bit for drilling a subterranean formation is provided. The drill bit includes at least one leg and a cantilevered bearing shaft that includes a base formed on the at least one leg and a substantially cylindrical surface extending from the base defining a longitudinal axis. The drill bit further includes a roller cone disposed about the bearing shaft, wherein the roller cone is configured to rotate about the longitudinal axis. The roller cone includes an exterior surface for contacting the subterranean formation and an interior surface disposed about the bearing shaft. A sealing element is disposed circumferentially about the bearing shaft and is positioned between the interior surface of the roller cone and an exterior surface of the bearing shaft. The drill bit includes a first bearing sleeve secured to base of the bearing shaft, thereby forming a portion of the exterior surface of the bearing shaft that contacts the sealing element, and a second bearing sleeve secured to the bearing shaft adjacent to the first bearing sleeve, thereby forming a portion of the exterior surface of the bearing shaft that contacts the interior surface of the roller cone. At least a portion of the exterior surface of the first bearing sleeve that contacts the sealing element includes a diamond-like carbon coating.

In another aspect, a method for reducing wear of an elastomeric seal in a drill bit is provided. The method includes the steps of providing a drill bit that includes at least one leg, a cantilevered bearing shaft that includes a base formed at the at least one leg and a substantially cylindrical surface extending from the base defining a longitudinal axis, wherein the bearing shaft having a lateral side surface, and a roller cone disposed about the bearing shaft. The roller cone is configured to rotate about the longitudinal axis, and includes an exterior surface that includes a plurality of cutting elements for contacting the subterranean formation and an interior surface disposed about the bearing shaft. An elastomeric shaft seal is positioned between the lateral side surface of the bearing shaft and the interior of the roller cone, and prevents the influx of unwanted fluids into an interior space defined by the interior surface of the roller cone and the bearing shaft. The method further includes the step of applying a wear resistant coating to the bearing shaft where it contacts the elastomeric shaft seal ring. In certain embodiments, the wear resistant coating includes diamond-like carbon.

### BRIEF DESCRIPTION OF THE DRAWINGS

FIG. 1 is a partial cross sectional view of a roller cone drill bit according to one embodiment of the invention.

FIG. 2 is a schematic view of one embodiment of a seal design for a seal counter surface.

FIG. 3 is a cross-sectional view of a portion of a roller cone bit according to one embodiment of the invention.

FIG. 4 is a cross-sectional view of a portion of a roller cone bit according to one embodiment of the invention.

FIG. 5 is a cross-sectional view of a portion of a roller cone bit according to one embodiment of the invention.

FIG. 6 is a view of the wear on a bearing shaft.

FIG. 7 is graphical representation of the profile of the wear groove shown in FIG. 5.

FIG. 8 is a view of the wear on a seal element.

FIG. 9a is a view showing the wear on a bearing shaft without a DLC coating after simulated use.

FIG. 9b is a view showing wear on a bearing shaft having a DLC coating after simulated use.

FIG. 10 is a graphical representation comparing the profile of the wear groove for a bearing shaft having a DLC coating according to one embodiment of the present invention and the wear groove for a bearing shaft without the DLC coating.

### DETAILED DESCRIPTION

Although the following detailed description contains many specific details for purposes of illustration, one of ordinary skill in the art will appreciate that many variations and alterations to the following details are within the scope and spirit of the invention. Accordingly, the exemplary embodiments of the invention described herein are set forth without any loss of generality to, and without imposing limitations thereon, the present invention.

Various materials known in the art can be used to provide surface treatments for the exterior surfaces of drill bits. Surface treatments can be applied to the exterior surface of the drill bits for a variety of reasons, such as increased life time of the exposed parts, and/or to reduce adhesion of various substances to the exterior surfaces of the drill bit. In contrast, the present invention relates to the application of surface treatments to the interior contacting surfaces of the drill bit. More specifically, the present invention is directed to the use of wear resistant coatings on the interior surface of the roller cone drill bits to reduce wear of the seal, resulting in increased life of both the metal surfaces and the seals.

One exemplary wear resistant surface coating is diamond-like carbon (DLC). DLC is a form of meta-stable amorphous carbon or hydrocarbon compound with physical properties very similar to those of diamond. Being amorphous, there are typically no grain boundaries. DLC coating is a carbon coating that includes a mixture of sp³ and sp² hybridized carbon atoms. The sp³ hybridized carbons form a tetrahedral crystalline orientation found in diamond. The sp² hybridized carbons have a planar crystalline structure, like that found in graphite. Technically, the sp³ hybridization means that the carbon reconfigures one s-orbital and three p-orbitals to form four identical sp³ orbitals having a tetrahedral configuration for bonding with the adjacent carbon atom. The sp² hybridized orbital is derived from one s-orbital and two p-orbitals to form three sp² orbitals, which are planar in orientation. DLC coatings have a certain percentage of both types hybridized carbons, depending upon how the material is prepared, thus the hardness of a DLC coating can be designed to be between that of diamond and graphite. The DLC coating has a hardness of between about 2000 and 5000 knoop, depending upon the amount of sp² and sp³ hybridized carbons and other impurities present in the coating.

In certain embodiments, the proportions of sp² and sp³ hybridized carbons in the DLC can be varied. A DLC coating having a higher concentration of sp³ hybridized carbon atoms typically has a greater hardness than the DLC coatings having a lower concentration of sp³ hybridized carbon atoms. Without wishing to be bound by any specific theory, it is believed that the graphitic sp² carbons present in the DLC coating contribute lubricious properties to the coating, resulting in a smooth, corrosion resistant surface. While the greater concentration of sp² carbon atoms typically results in a softer coating, it also has a higher lubricity. The exact combination of hardness and lubricity can be adjusted based upon the desired properties of the end product. In addition to carbon, DLC coatings can also include a variety of impurities, such as hydrogen and/or metal atoms. Hydrogen is typically present as a result of the process gas used during fabrication, because DLC coatings are deposited by the decomposition of a carbon compound and hydrogen compound. One suitable DLC precursor carbon compound is acetylene.

The diamond-like carbon coatings of the present invention can be applied by a variety of techniques, including but not limited to, physical vapor deposition, chemical vapor deposition, vacuum deposition and like processes. Physical vapor deposition processes can include evaporation, sputtering and laser ablation. Chemical vapor deposition (CVD) processes generally include the deposition of a solid from the vapor phase onto a substrate that optionally may be heated or pretreated by other means to enhance the reaction of the material being deposited with the substrate surface. In certain embodiments, DLC is applied from high energy carbon precursors that are produced by a plasma, sputter deposition, ion beam deposition, or the like. In other embodiments, the DLC layer can be applied by deposition from an RF (radio frequency) plasma, sustained in hydrocarbon gases, onto negatively biased substrate surface. The DLC coating can be applied directly to the surface being coated, or to a metal interlayer that has been applied to the surface being coated. Generally, the DLC coating can be applied to any substrate that is compatible with a vacuum deposition environment.

In one exemplary embodiment, the DLC coating can be applied in the following manner. DLC is applied by deposition from an RF (radio frequency) plasma, sustained in hydrocarbon gases, onto a negatively biased substrate surface. In this process, referred to as a plasma assisted chemical vapor deposition (PACVD), the substrate surface is typically heated by an electron current to a temperature that is below their lowest transformation temperature. Electrons from the electron current are attracted to the face of the substrate surface from a plasma beam in the center of the chamber. After heating, the substrate surface can be etched by argon ion bombardment or a like process. For this, the substrate surface is typically biased to a negative potential to attract argon ions from a plasma source. This process cleans the surfaces by etching.

After cleaning of the substrate surface has been completed, one or more metallic interlayers, such as chromium, can optionally be applied to the substrate surface from a sputter source. Sputtering is similar to etching, however a bias voltage is applied to the metal (e.g., chromium) target of several hundred volts. The substrate being coated with the metal serves as a negative electrode. Material is removed from the metal target surface by the impact of argon ions, and this material then condenses onto the target substrate surface. Depending upon the material of the substrate being coated, the optional metallic interlayer prepared in this manner can be used to increase adhesion of the DLC coating and can be formed of a variety of metals, such as titanium.

After the optional deposition of the metal interlayer on the surface of the substrate, acetylene or another carbon source can be introduced and a plasma can be ignited between substrate surface and the chamber walls. Decomposition of the carbon source results in the formation of individual carbon atoms that coat the substrate surface or the optional metallic interlayer of the substrate with DLC. DLC coatings are insulating, thus the plasma for the DLC cannot be a DC plasma, but must instead be an AC plasma. Typically an RF plasma is used. After coating the substrate with the DLC coating, the substrate is cooled and the deposition chamber vented. During the entire DLC coating process, the temperature in the deposition chamber is preferably maintained at below the lowest transformation temperature of the substrate.

In addition to the process of applying the DLC coating described above, other processes are suitable for the deposition of the DLC, including primary ion beam deposition of carbon items (IBD). Another process that may be suitable is sputter deposition of carbon, either with or without bombardment by an intense flux of ions (physical vapor deposition). Yet another technique is based on closed field unbalanced magnetron sputter ion plating, combined with plasma assisted chemical vapor deposition. The deposition can be carried out at approximately 200° C. in a closed field unbalanced magnetron sputter ion plating system.

The DLC, as applied, can have a thickness between approximately 0.5 μm and 100 μm. Preferably the DLC coating has a thickness of between approximately 1 μm and 10 μm. The optional intermetallic layer can have a thickness of between about 0.5 μm and 10 μm, and is preferably minimized.

In certain embodiments, multilayer compositions can be prepared. The multilayer composition is prepared by repeating the steps of applying the DLC coating to the surface being coated.

In certain embodiments, an alternate coating can be applied to the bearing shaft surface that contacts the seal. For example, in certain embodiments, a wear and corrosion resistant coating selected from hardfacing, Hardide™, TiN or SiC can be applied by known means to the bearing shaft surface. A lubricant layer, selected from Teflon, hexagonal boron nitride, graphite, tungsten disulfide or molybdenum disulfide, or a like material, can then be applied to the wear resistant coating.

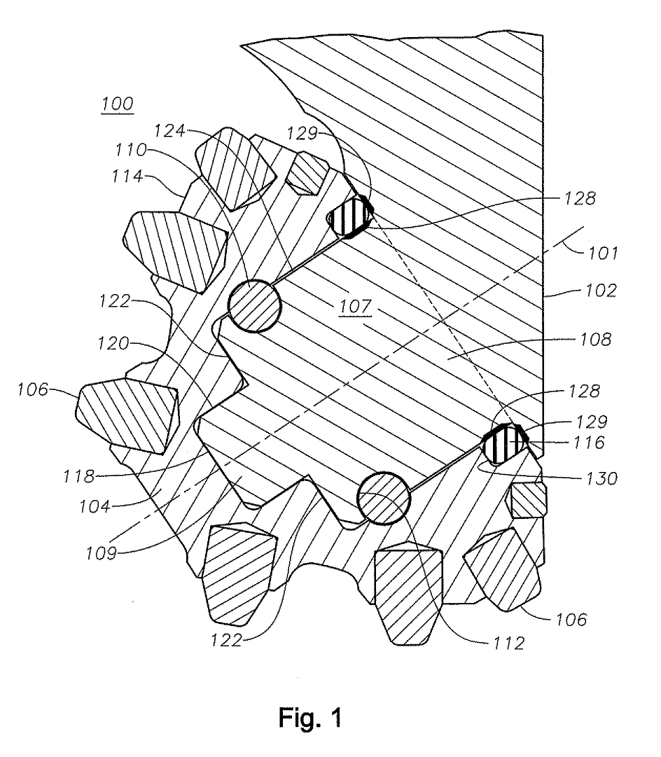

FIG. 1 shows a partial cross sectional view of one embodiment of a roller cone drill bit bearing according to the present invention. Drill bit 100 includes leg 102 coupled to a cone 104 via bearing shaft 107. Bearing shaft 107 extends from leg 102 and has a longitudinal axis of rotation 101. Cone 104 includes a plurality of cutting inserts 106. Bearing shaft 107 includes base 108 and head 109, wherein the base and head of the bearing shaft are substantially cylindrical, and wherein the base has a larger diameter than the head. A plurality of locking balls 110 are retained in bearing race 112, which operably retains cone 104 on bearing shaft 107. Primary thrust face 122 is located on bearing shaft 107. Secondary thrust face 118 is positioned at the distal end of bearing shaft head 109. Seal 116 is positioned between end of base 108 of bearing shaft 107, proximate to leg 102. Seal 116 can be an o-ring or the like, and can be composed of an elastomeric rubber or like material.

In accordance with the present invention, a DLC coating can be applied to lateral surface 128 of bearing shaft 107, which contacts seal 116. Additionally, the DLC coating can be applied to any surface seal 116 contacts, such as back face plane 129 or forward face plane 130.

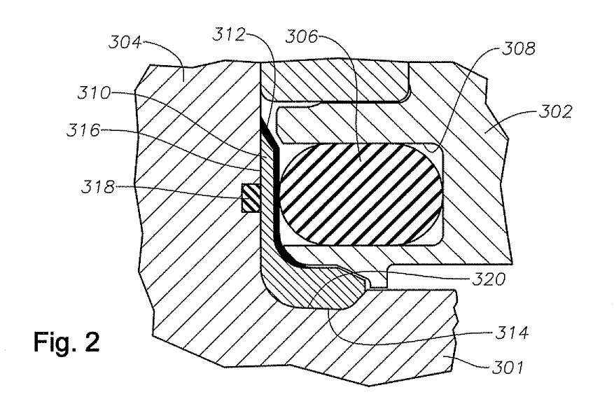

FIG. 2 illustrates a schematic view of a seal design for use on a roller cone drill bit having a floating sleeve. The drill bit consists of roller cone 302 positioned about bearing shaft 304, which is connected to leg 301. Cone 302 includes an outer surface and an interior cavity, which are formed to operably engage bearing shaft 304. The seal between cone 302 and bearing shaft 304 can include elastomeric seal 306 positioned in seal groove 308, formed near the entrance or mouth of the interior cavity of the cone. The seal also includes rigid floating sleeve 310 positioned on bearing shaft 304 at the junction with drill bit leg 301. Rigid floating sleeve 310 preferably has an L-shaped cross-section, having cylindrical portion 316 that extends around the lateral edge of bearing shaft 304 and flange portion 314 that extends outward from the cylindrical portion and engages annular recess 320. Inner seal 318 is located in a groove formed in bearing shaft 304, and seals against the inner diameter of cylindrical portion 316 of floating sleeve 310. Inner seal 318 can be an elastomeric o-ring, and preferably has a uniform cross-sectional thickness about the circumference of the seal. Floating sleeve 310 typically remains stationary with bearing shaft 304; however some rotation or slippage may occur. A DLC coating 312 can be applied to the exterior face of cylindrical portion 316 of floating sleeve 310, at the location where the sleeve contacts elastomeric seal 306. In certain embodiments, a DLC coating is applied to the interior surface of floating sleeve 310, where the sleeve contacts bearing shaft 304.

As described herein, methods for the preparation of drill bits that include a wear resistant surface are also provided. The wear resistant surface is generally applied to at least one of the contacting surfaces between the interior of the roller cone and the exterior of the bearing shaft.

Typically, the drill bit body is prepared as three separate pieces or “thirds”, which after assembly, are welded together to make the drill bit. The manufacture of a drill bit having wear resistant surfaces according to the methods described herein includes the steps of providing a third, wherein the third includes a drill bit leg and a cantilevered bearing shaft formed on the end the drill bit leg. The drill bit leg may then be masked off, leaving exposed only the surfaces to which the wear resistant coating is desired to be applied. The masked drill bit leg may then be positioned in a vacuum deposition chamber, and the desired materials may be deposited thereon. Preferably, at least a portion of the bearing shaft is left exposed and coated with a wear resistant coating. In certain embodiments, the chamber may be heated and maintained at a reduced pressure during the deposition. One preferred coating for the bearing shaft is a tungsten/tungsten carbide coating. Following deposition of a wear resistant coating of desired thickness, the drill bit leg having the wear resistant coating is removed from the deposition chamber, the masking is removed, and the drill bit is assembled. Assembly of the drill bit includes the steps of positioning a roller cone on the bearing shaft which has the wear resistant surface coating applied thereto, securing the roller cone to the bearing shaft by inserting the locking balls into the locking ball race, and welding three similarly configured thirds together to achieve the drill bit, such as for example, by electron beam welding.

In an alternate embodiment, the manufacture of a drill bit having wear resistant DLC surfaces according to the methods described herein can include the step of providing a masked bearing shaft, wherein the exposed surfaces of the bearing shaft are desired to be coated with the DLC coating. Preferably, the bearing shaft, to which the cone is attached when the drill bit is assembled, includes a DLC coating. The masked bearing shaft may be positioned in a vacuum deposition chamber, and the desired DLC material deposited thereon. In certain embodiments, the chamber is heated and maintained at an elevated pressure, during the deposition of the coating. Following deposition of a surface coating of desired thickness, the bearing shaft may be removed from the deposition chamber, the masking removed, and the drill bit assembled. During assembly, the roller cone is positioned on a bearing shaft which has a DLC coating applied to at least a portion of the exterior surface, and locking balls are inserted into a locking ball race, thereby securing the roller cone to the bearing shaft. Typically, the drill bit is prepared as the separate pieces or “thirds”, which after securely fastening the roller cones to the bearing shaft, are welded together to make the drill bit.

In certain embodiments, a sleeve can be installed on the bearing shaft, wherein the sleeve includes a wear resistant DLC coating applied to the exterior surface. Methods for application of the wear resistant coating on the surface of the sleeve are provided herein, and can include physical and chemical vapor deposition. Techniques for the use of bearing sleeves are described in U.S. Pat. Nos. 7,387,177 and 7,392,862, the disclosures of which are hereby incorporated in their entirety. In certain embodiments, the sleeve that includes a wear resistant coating can be secured to a bearing shaft that is adapted to receive said sleeve. Methods for affixing or securing the sleeve to the bearing shaft include welding, brazing, gluing, soldering, shrink fitting, pinning, splining, combinations thereof, or the like.

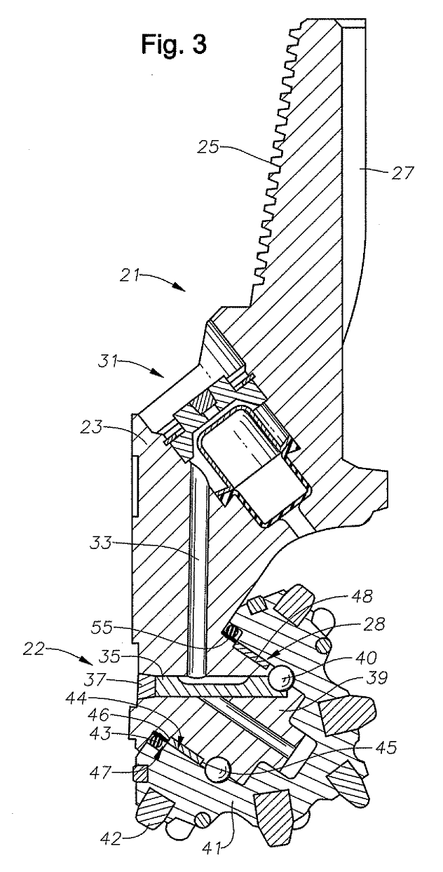

FIG. 3 provides is a partial sectional view of earth-boring bit 21 that includes journal bearing element 28. While FIG. 3 only illustrates a single section, bit 21 may include two or more sections welded together to form composite drill bit 21. Earth-boring bit 21 has bit body 23 with threaded upper portion 25 for connecting to a drill string member (not shown) and leg section 22 having cutting cone 41 attached thereon. Fluid passage 27 directs drilling fluid to a nozzle (not shown) that impinges drilling fluid against the borehole bottom to flush cuttings to the surface of the earth. Pressure compensating lubrication system 31 may optionally be contained within each section of bit 21. Lubrication passage 33 extends downwardly to ball plug 35, which is secured to body 21 by plug weld 37. A third lubrication passage (not shown) carries lubricant to a bearing surface between bearing shaft 39, which is cantilevered downwardly and inwardly from an outer and lower region of body 23 of bit 21. Ball plug 37 retains a series of ball bearings 40 rotatably secured to cutter cone 41 and to bearing shaft 39. Dispersed in cutter cone 41 are a plurality of rows of earth disintegrating cutting elements or teeth 42 securable by interference fit in mating holes of cutter cone 41. Elastomeric o-ring seal 43 is received within recess 47 formed in cutter cone 41. A DLC coating 55 is applied to bearing shaft 39 at the point where the bearing shaft contacts elastomeric o-ring 43.

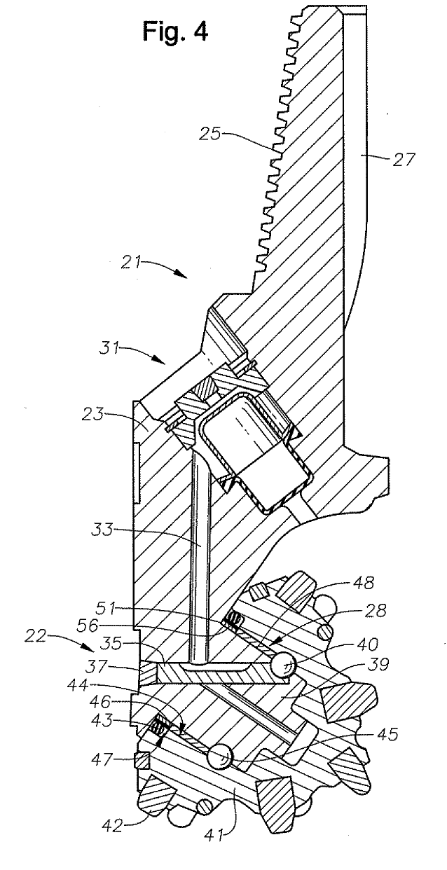

FIG. 4 provides an alternate embodiment, wherein the DLC coating has been applied to bearing sleeve 51, which is then secured about bearing shaft 39. As described previously, bearing sleeve 51 includes a DLC coating 56 applied to the exterior surface (i.e., the surface that contacts seal 43), and can be secured to bearing shaft 39 by a variety of means, including welding, brazing, gluing, soldering, shrink fitting, pinning, splining, combinations thereof, or the like. In certain embodiments, the DLC coated bearing sleeve 51 may extend beyond the seal and contact a portion of the cone.

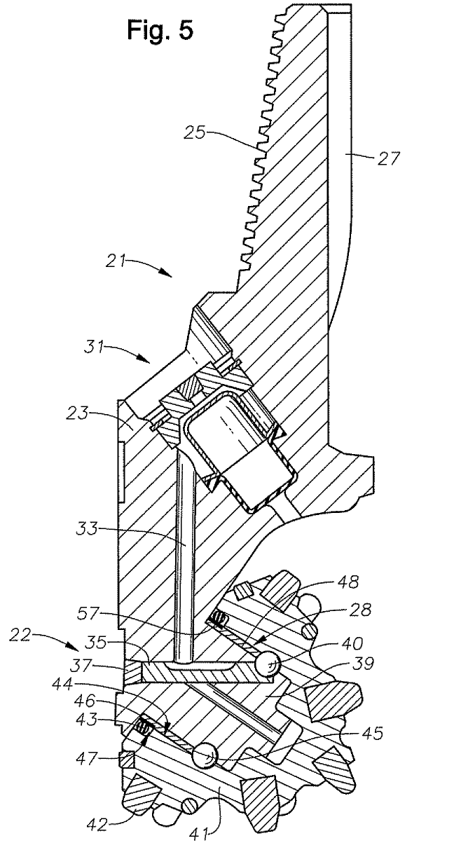

FIG. 5 provides yet another alternate embodiment, wherein the DLC coating 57 has been applied to only the portion of journal bearing sleeve element 28 that contacts elastomeric o-ring seal 43. Thus, journal bearing sleeve element 28 is inserted onto bearing shaft 39 and secured by welding, brazing, gluing, soldering, shrink fitting, pinning, splining, combinations thereof, or the like.

### EXAMPLES

A 12.25 inch tri-cone drill bit not having a wear and corrosion resistant coating applied to the portion of the bearing shaft that contacts the elastomeric seal was run in a drilling field application. The drill bit was used to drill a borehole for a period of at least 34 hours, and was rotated at approximately 220 rpm or greater.

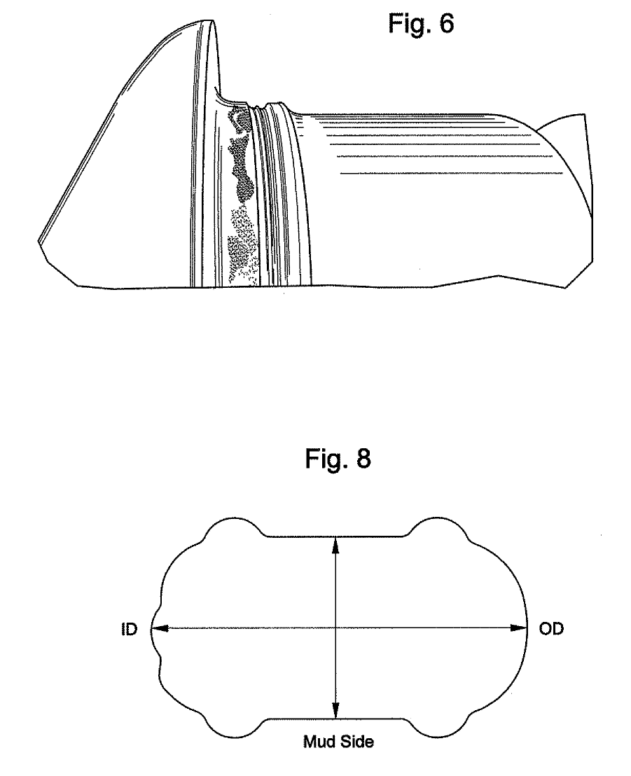

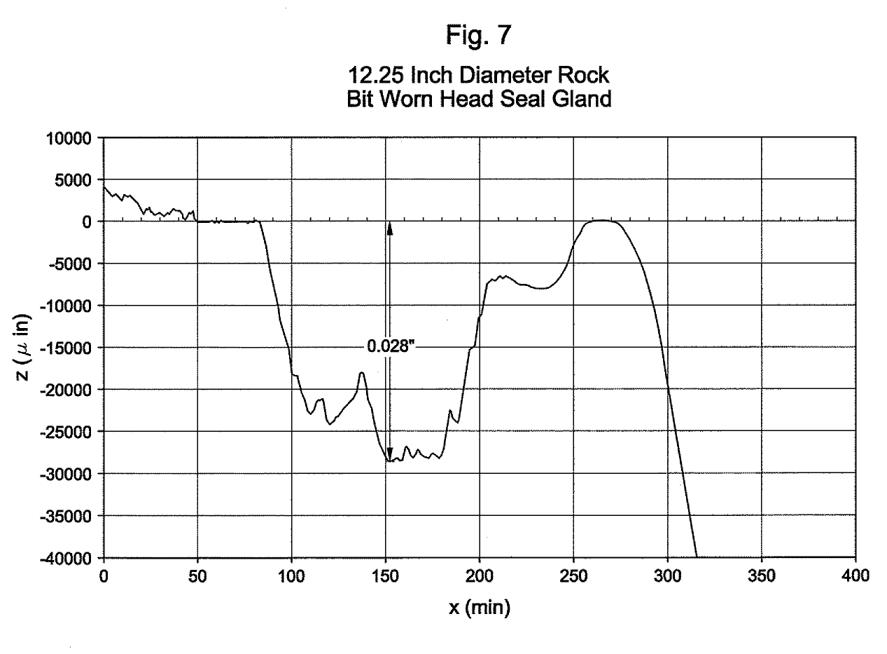

The uncoated drill bit showed significant wear on both the bearing shaft and the seal after completion of the run. As shown in FIG. 6, the bearing shaft clearly shows scoring on the surface thereof. Additionally, as shown graphically in FIG. 7, the groove that has been worn in the surface of the bearing shaft, as measured using a contacting profilometer, is about 0.028 inches deep. The corresponding wear on the seal is shown in FIG. 8, wherein the width of the seal cross section has been reduced on the inner diameter due to sliding contact with the bearing shaft. As used herein, the width of the seal is defined as distance between the inner diameter (ID) and the outer diameter (OD) of the seal.

As used herein, squeeze is defined as: (seal width minus the gland width)/seal width. The loss of the width of the seal cross section is responsible for the loss of approximately 50% of the squeeze of the seal. The wear on the seal gland of the bearing shaft is responsible for a loss of approximately 68% of the squeeze of the seal. Overall, the combined wear on the seal and the bearing resulted in a loss of approximately all of the squeeze on the seal. Additionally, it should be noted that the bearing shaft wear is larger when compared with the seal wear. This suggests the wear reduction of the bearing shaft as described in this invention can significantly improve retention of seal squeeze and thus drill bit lifetime.

Furthermore, analysis of the fluids (grease) in the drill bit showed high contamination with drilling fluids. Specifically, while the increase of silicon present in the drill bit grease at the reservoir of the drill bit was relatively low, in contrast, the concentration of silicon at the bearing increased by a factor of approximately 15, relative to a normalized silicon concentration for an uncontaminated sample.

A second test was conducted to simulate normal usage of a rock drill bit, wherein two seal test fixtures, consisting of the portion of the bearing shaft that is in sliding engagement with the seal, one coated with a DLC coating about the bearing shaft where the seal contacts the bearing shaft and one uncoated, were submerged in drilling mud and operated. The drilling mud was maintained at a temperature of approximately 150° F. and the cones were rotated at a rate of about 240 rpm for 48 hours. Sand in the mud was injected into the gland with a pump to simulate an abrasive environment.

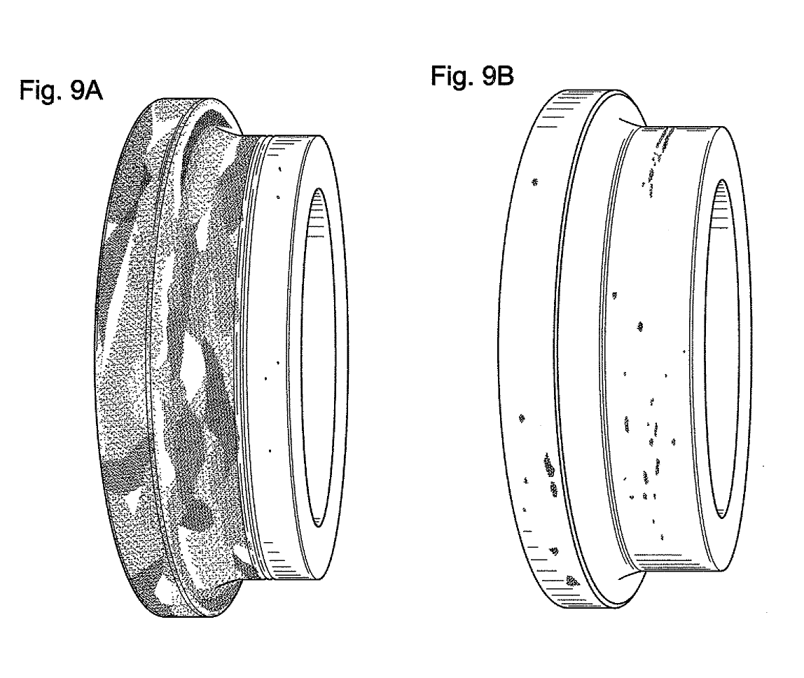

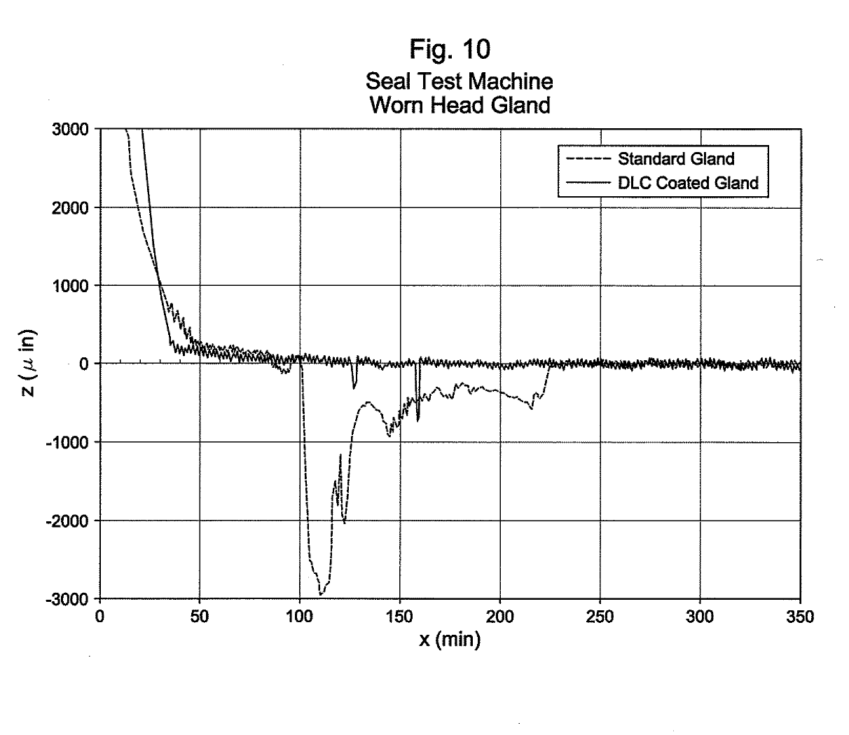

FIG. 9b shows a view of a DLC coated seal test fixture and FIG. 9a shows a view of an uncoated seal test fixture, wherein the uncoated seal test fixture shows a significant groove in surface and significant corrosion, whereas the DLC coated surface shows little or no loss of the surface and significantly less corrosion. FIG. 10 provides a graphical comparison of the wear on seal test fixture having no DLC coating at the seal fixture point of contact and the wear on the seal test fixture having the DLC coating at the seal fixture point of contact. As shown, the uncoated surface shows significant scoring and the formation of a groove (as evidenced by the depth profile measurement), whereas the coated surface shows almost no scoring over the time period of the test.

As used herein, recitation of the term about and approximately with respect to a range of values should be interpreted to include both the upper and lower end of the recited range.

As used in the specification and claims, the singular form “a”, “an” and “the” may include plural references, unless the context clearly dictates the singular form.

Although some embodiments of the present invention have been described in detail, it should be understood that various changes, substitutions, and alterations can be made hereupon without departing from the principle and scope of the invention.

1. A drill bit for drilling a subterranean formation, comprising:
at least one leg;
a cantilevered bearing shaft comprising a base formed on the at least one leg and having a substantially cylindrical surface extending from the base defining a longitudinal axis;
a roller cone disposed about the bearing shaft and configured to rotate about the longitudinal axis, said roller cone comprising an exterior surface for contacting the subterranean formation and an interior surface disposed about the bearing shaft; and
a sealing element disposed circumferentially about the bearing shaft positioned between the interior surface of the roller cone and an exterior surface of the bearing shaft;
wherein at least a portion of the exterior surface of the bearing shaft that contacts the sealing element comprises a diamond-like carbon coating.

2. The drill bit of claim 1 wherein the diamond-like carbon coating is applied to an exterior surface of the bearing shaft by plasma assisted chemical vapor deposition.

3. The drill bit of claim 1 further comprising applying an intermetallic layer to the bearing shaft prior to applying the diamond-like carbon coating.

4. The drill bit of claim 1 wherein the diamond-like carbon coating has a thickness of between about 0.5 and 100 μm.

5. The drill bit of claim 1 wherein the diamond-like carbon coating has a thickness of between about 1 and 10 μm.

6. A drill bit for drilling a subterranean formation, comprising:
at least one leg;
a cantilevered bearing shaft comprising a base formed on the at least one leg and having a substantially cylindrical surface extending from the base defining a longitudinal axis;
a roller cone disposed about the bearing shaft and configured to rotate about the longitudinal axis, said roller cone comprising an exterior surface for contacting the subterranean formation and an interior surface disposed about the bearing shaft; and
a sealing element disposed circumferentially about the bearing shaft positioned between the interior surface of the roller cone and an exterior surface of the bearing shaft;
a bearing sleeve secured to the bearing shaft, thereby forming at least a portion of the exterior surface of the bearing shaft that contacts the sealing element;
wherein at least a portion of the exterior surface of the bearing sleeve that contacts the sealing element comprises a diamond-like carbon coating.

7. The drill bit of claim 6 wherein the diamond-like carbon coating is applied to an exterior surface of the bearing sleeve by plasma assisted chemical vapor deposition.

8. The drill bit of claim 6 further comprising applying an intermetallic layer to the bearing sleeve prior to applying the diamond-like carbon coating.

9. The drill bit of claim 6 wherein the bearing sleeve is secured by welding, brazing, gluing, soldering, shrink fitting, pinning, splining or combinations thereof, or the like.

10. The drill bit of claim 6 wherein the diamond-like carbon coating has a thickness of between about 0.5 and 100 μm.

11. The drill bit of claim 6 wherein the diamond-like carbon coating has a thickness of between about 1 and 10 μm.

12. A drill bit for drilling a subterranean formation, comprising:
at least one leg;
a cantilevered bearing shaft comprising a base formed on the at least one leg and having a substantially cylindrical surface extending from the base defining a longitudinal axis;
a roller cone disposed about the bearing shaft and configured to rotate about the longitudinal axis, said roller cone comprising an exterior surface for contacting the subterranean formation and an interior surface disposed about the bearing shaft; and
a sealing element disposed circumferentially about the bearing shaft positioned between the interior surface of the roller cone and an exterior surface of the bearing shaft;
a first bearing sleeve secured to base of the bearing shaft, thereby forming a portion of the exterior surface of the bearing shaft that contacts the sealing element;
a second bearing sleeve secured to the bearing shaft adjacent to the first bearing sleeve, thereby forming a portion of the exterior surface of the bearing shaft that contacts the interior surface of the roller cone;
wherein at least a portion of the exterior surface of the first bearing sleeve that contacts the sealing element comprises a diamond-like carbon coating.

13. The drill bit of claim 12 wherein the diamond-like carbon coating is applied to an exterior surface of the first bearing sleeve by plasma assisted chemical vapor deposition.

14. The drill bit of claim 12 further comprising applying an intermetallic layer to the first bearing sleeve prior to applying the diamond-like carbon coating.

15. The drill bit of claim 12 wherein the first bearing sleeve is secured by welding, brazing, gluing, soldering, shrink fitting, pinning, splining or combinations thereof or the like.

16. The drill bit of claim 12 wherein the diamond-like carbon coating has a thickness of between about 0.5 and 100 μm.

17. The drill bit of claim 12 wherein the diamond-like carbon coating has a thickness of between about 1 and 10 μm.

18. A method for reducing wear of an elastomeric seal in a drill bit, comprising:
providing a drill bit, the drill bit comprising:
at least one leg;
a cantilevered bearing shaft comprising a base formed at the at least one leg and having a substantially cylindrical surface extending from the base defining a longitudinal axis, said bearing shaft having a lateral side surface;
a roller cone disposed about the bearing shaft and configured to rotate about the longitudinal axis, said roller cone comprising an exterior surface comprising a plurality of cutting elements for contacting the subterranean formation and an interior surface disposed about the bearing shaft;
an elastomeric shaft seal positioned between the lateral side surface of the bearing shaft and the interior of the roller cone, wherein the seal prevents the influx of unwanted fluids into an interior space defined by the interior surface of the roller cone and the bearing shaft;
applying a wear resistant coating to the bearing shaft where it contacts the elastomeric shaft seal ring.

19. The method of claim 18 wherein the wear resistant coating comprises diamond-like carbon.

20. The method of claim 18 wherein wear resistant coating applied to the bearing shaft has a thickness of between about 0.5 and 100 μm.
